(19) United States
(12) Patent Application Publication
(10) Pub. No.: US 2013/0177998 A1
(43) Pub. Date: Jul. 11, 2013

(54) METHOD OF MANUFACTURING LIGHT EMITTING DEVICE AND PHOSPHOR-CONTAINING FLUID RESIN DISPENSING APPARATUS

(71) Applicant: SAMSUNG ELECTRONICS CO., LTD., Gyeonggi-do (KR)

(72) Inventors: Jee Hun Hong, Gyeonggi-do (KR); Kook Jin Oh, Chungcheongnam-do (KR); Joung Min Oh, Chungcheongnam-do (KR)

(73) Assignee: SAMSUNG ELECTRONICS CO., LTD., Gyeonggi-do (KR)

(21) Appl. No.: 13/735,754

(22) Filed: Jan. 7, 2013

(30) Foreign Application Priority Data
Jan. 6, 2012 (KR) 10-2012-0001979

(51) Int. Cl. H01L 21/66; B67D 7/32

(52) U.S. Cl. CPC H01L 22/10; B67D 7/3281
USPC 438/15; 222/23

(57) ABSTRACT

There is provided a method of manufacturing a light emitting diode (LED) package, including discharging a predetermined discharge amount of a phosphor-containing fluid resin to at least one LED package, and measuring color coordinates of white light emitted from the at least one LED package. The method also includes adjusting a discharge amount of the phosphor-containing fluid resin, based on a deviation between the measured color coordinates and target color coordinates, so as to obtain the target color coordinates. The method further includes discharging the adjusted discharge amount of the phosphor-containing fluid resin to another LED package;, and curing the phosphor-containing fluid resin dispensed to the another LED package.

### CROSS-REFERENCE TO RELATED APPLICATION

This application claims the priority to Korean Patent Application No. 10-2012-0001979 filed on Jan. 6, 2012, in the Korean Intellectual Property Office, the disclosure of which is incorporated herein by reference.

### FIELD

The present inventive concept relates to a method of manufacturing a light emitting device. The method uses a phosphor-containing fluid resin dispensing apparatus to manufacture a light emitting device which includes a wavelength conversion unit.

### BACKGROUND

A light emitting diode (hereinafter, referred to as an “LED”) is a semiconductor device which converts electrical energy into optical energy and comprises a compound semiconductor which emits light of a particular wavelength according to an energy band gap. The use of LEDs has become widespread in back light units (BLU) of display devices such as an optical communications display or a mobile display device, a computer monitor, or the like, for a liquid crystal diode (LCD), and as a general illumination device.

In order to provide white light, LED packages include a suitable wavelength conversion unit. However, even when a light emitting package is manufactured through a single process, there may be an occurrence of white light having different color properties. This variation in color properties may be due to a process error during the formation of a wavelength conversion unit. As a consequence, defects such as irregular color scattering may occur.

In some cases, light emitting diode packages may provide white light that deviates from the range of conditions of required target color properties,thereby resulting in defective light emitting diode packages and decreased production yields.

### SUMMARY

An aspect of the present disclosure provides a method of manufacturing a light emitting device, capable of providing white light satisfying target color properties while significantly reducing a drop in production yield through a simplified process.

An aspect of the present disclosure provides a method of manufacturing a light emitting diode (LED) package, including dispensing a predetermined discharge amount of a phosphor-containing fluid resin to at least one LED package, and measuring color coordinates of white light emitted from the at least one LED package. The method includes adjusting the discharge amount of the phosphor-containing fluid resin based on a deviation between the measured color coordinates and target color coordinates. The method further includes dispensing the adjusted discharge amount of the phosphor-containing fluid resin to another LED package.

The method may also include curing the phosphor-containing fluid resin dispensed to the another LED package.

The measuring of the color coordinates may be performed before the dispensed phosphor-containing fluid resin is cured.

The LED package may include a blue LED chip, and the phosphor-containing fluid resin may include at least one of a yellow phosphor and a mixture of red and green phosphors. In this case, the adjusting of the discharge amount of the phosphor-containing fluid resin may be performed to increase the predetermined discharge amount when the deviation corresponds to a blue shift and to reduce the predetermined discharge amount when the deviation corresponds to a red shift or yellow shift.

The adjusting of the discharge amount of the phosphor-containing fluid resin may be performed within an adjustable range to be allowed in the LED package.

The adjusting of the discharge amount of the phosphor-containing fluid resin may be performed to calculate the discharge amount of the phosphor-containing fluid resin by using a correlation between the deviation and the discharge amount to compensate for the deviation.

The correlation between the deviation and the discharge amount may be obtained by dispensing different discharge amounts of the phosphor-containing fluid resin dispensed thereto to two LED packages, measuring the color coordinates of the white light emitted from the two LED packages, and then performing a calculation by using a change in the discharge amount and the deviation of the color coordinates of the two LED packages.

The at least one LED package may be at least one LED package provided in a lead frame set on which a plurality of the LED packages are disposed, and the another LED package may be another LED package balanced in the lead frame set on which the plurality of the LED packages are disposed. In a specific case, the another LED package may further include a plurality of other LED packages in another lead frame set.

According to another aspect, there is provided a dispensing apparatus including a dispenser including a fluid resin storage unit storing a phosphor-containing fluid resin, a discharge unit dispensing the phosphor-containing fluid resin to an LED package, and a discharge amount control unit controlling a discharge amount of the phosphor-containing fluid resin discharged from the discharge unit. The apparatus also includes a discharge amount adjuster including an electric driving unit electrically driving the LED package, and a color coordinates measuring unit detecting color coordinates of light emitted from the LED package. In addition, the apparatus includes a discharge amount calculation unit calculating the discharge amount of the phosphor-containing fluid resin, based on a deviation between the measured color coordinates and target color coordinates, to obtain the target color coordinates, and a control signal transmission unit transmitting a control signal based on the calculated discharge amount to the discharge amount control unit.

The color coordinates measuring unit may be integrally disposed with the dispenser so as to measure color coordinates provided before the phosphor-containing fluid resin dispensed to the LED package is cured.

Another aspect of the present disclosure provides a method of manufacturing a light emitting diode (LED) package, including dispensing a discharge amount of a phosphor-containing fluid resin to at least one LED package, and measuring color coordinates of white light emitted from the at least one LED package. The method also includes adjusting the discharge amount of the phosphor-containing fluid resin such that the measured color coordinates become approximate to the target color coordinates range. The method further includes dispensing the adjusted discharge amount of the phosphor-containing fluid resin to another LED package. In addition, the method may include repeating the aforementioned dispensing, measuring, adjusting, and dispensing steps.

### BRIEF DESCRIPTION OF THE DRAWINGS

FIG. 1 is a flowchart illustrating a method of manufacturing a light emitting device according to an embodiment of the present disclosure; FIGS. 2 and 3 show CIE 1931 chromaticity coordinates for explaining an adjustment process for target color coordinates, based on control of a discharge amount of a phosphor-containing fluid resin;

FIG. 4 schematically shows a dispensing apparatus according to another embodiment of the present disclosure;

FIG. 5 is an enlarged cross-sectional view of an LED package in a lead frame set shown in FIG. 4;

FIG. 6 is CIE 1931 chromaticity coordinates for explaining a change in color coordinates accordance to an adjustable range to be allowed according to an embodiment of the present disclosure;

FIG. 7 is a flowchart illustrating a process of deriving a correlation between a deviation and a discharge amount according to an embodiment of the present disclosure; and

FIG. 8 illustrates a correlation between first and second discharge amounts and target reference color coordinates used in FIG. 7.

### DETAILED DESCRIPTION OF THE EMBODIMENTS

In the following detailed description, numerous specific details are set forth by way of examples in order to provide a thorough understanding of the relevant teachings. However, it should be apparent to those skilled in the art that the present teachings may be practiced without such details. In other instances, well known methods, procedures, components, and/or circuitry have been described at a relatively high-level, without detail, in order to avoid unnecessarily obscuring aspects of the present teachings.

In addition, like or similar reference numerals denote parts performing similar functions and actions throughout the drawings.

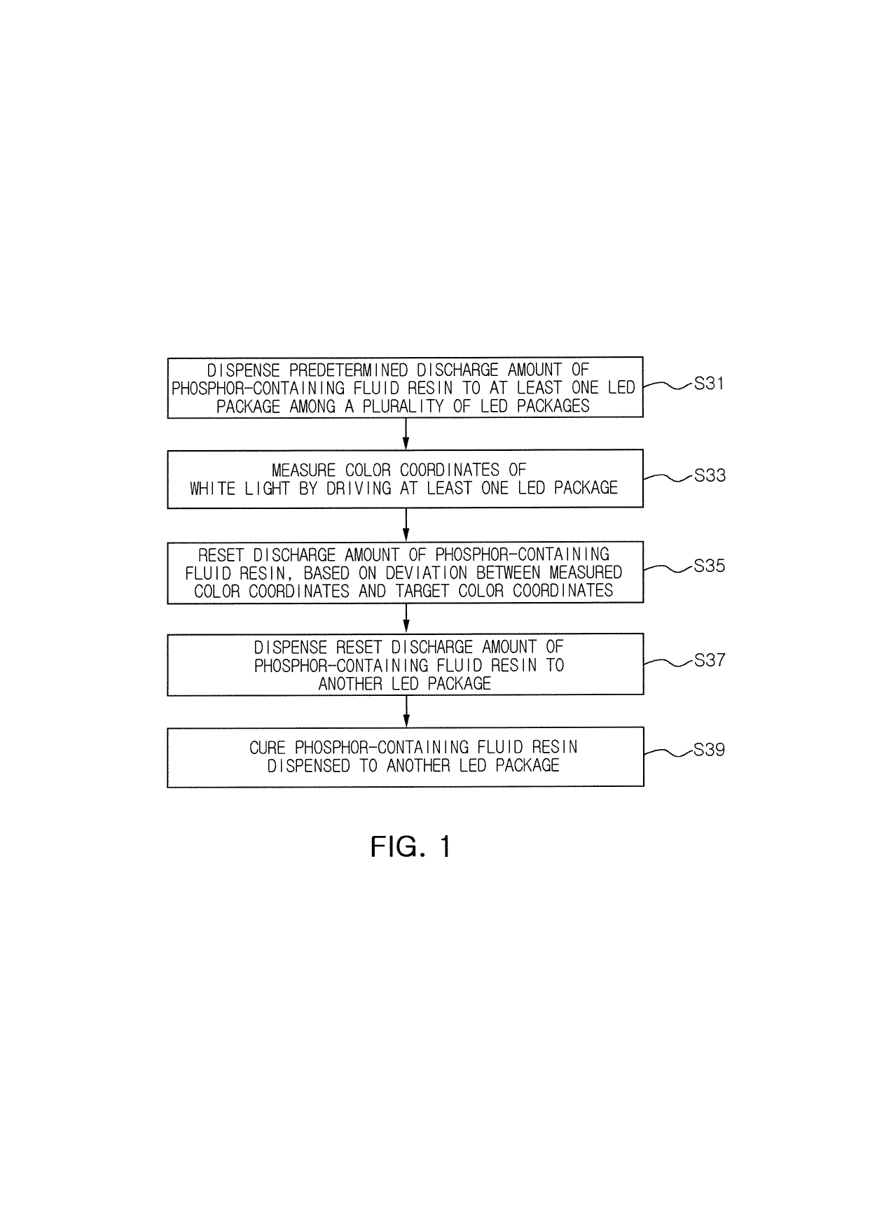

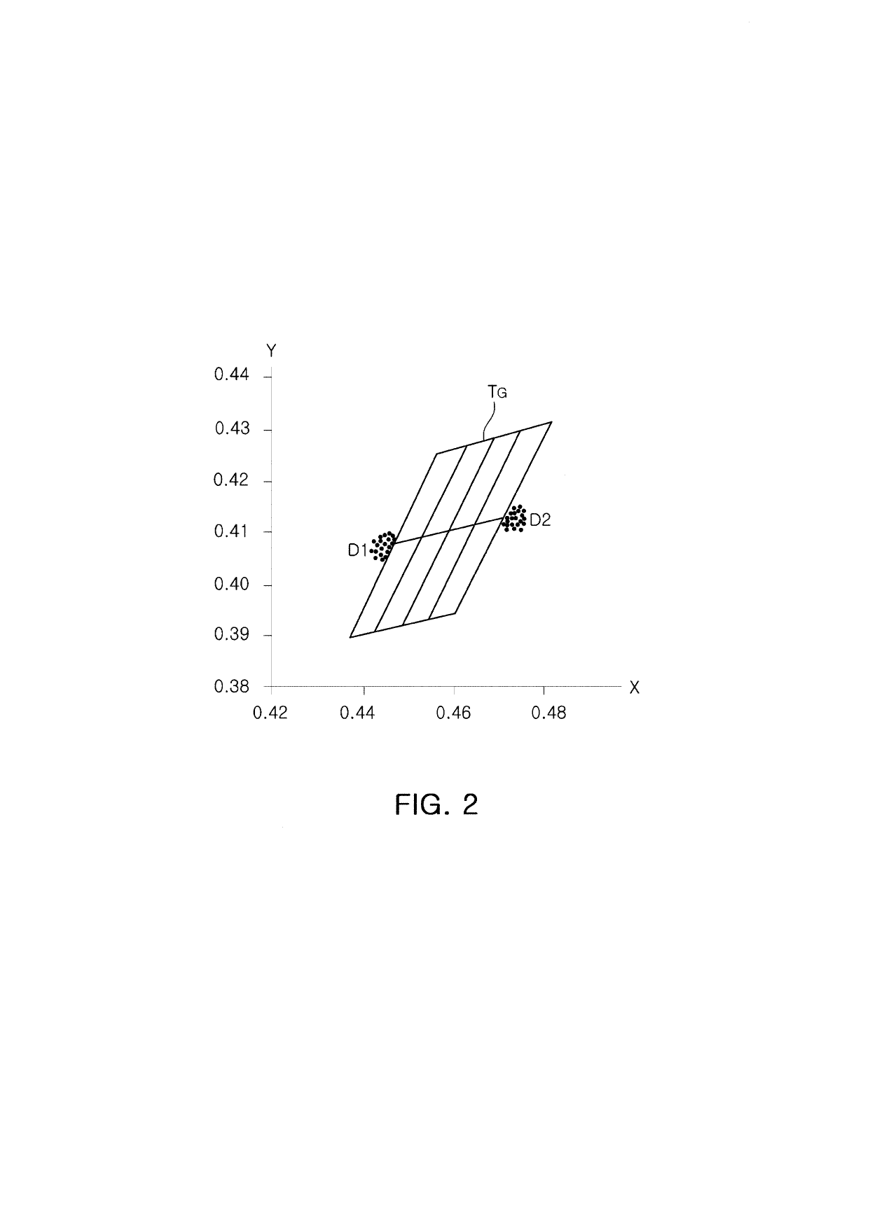

FIG. 1 is a flowchart illustrating a method of manufacturing a light emitting device according to an embodiment of the present disclosure.

The method of manufacturing a light emitting device according to an embodiment of the present disclosure may be performed starting with operation S31 of dispensing a predetermined discharge amount of phosphor-containing fluid resin to at least one LED package.

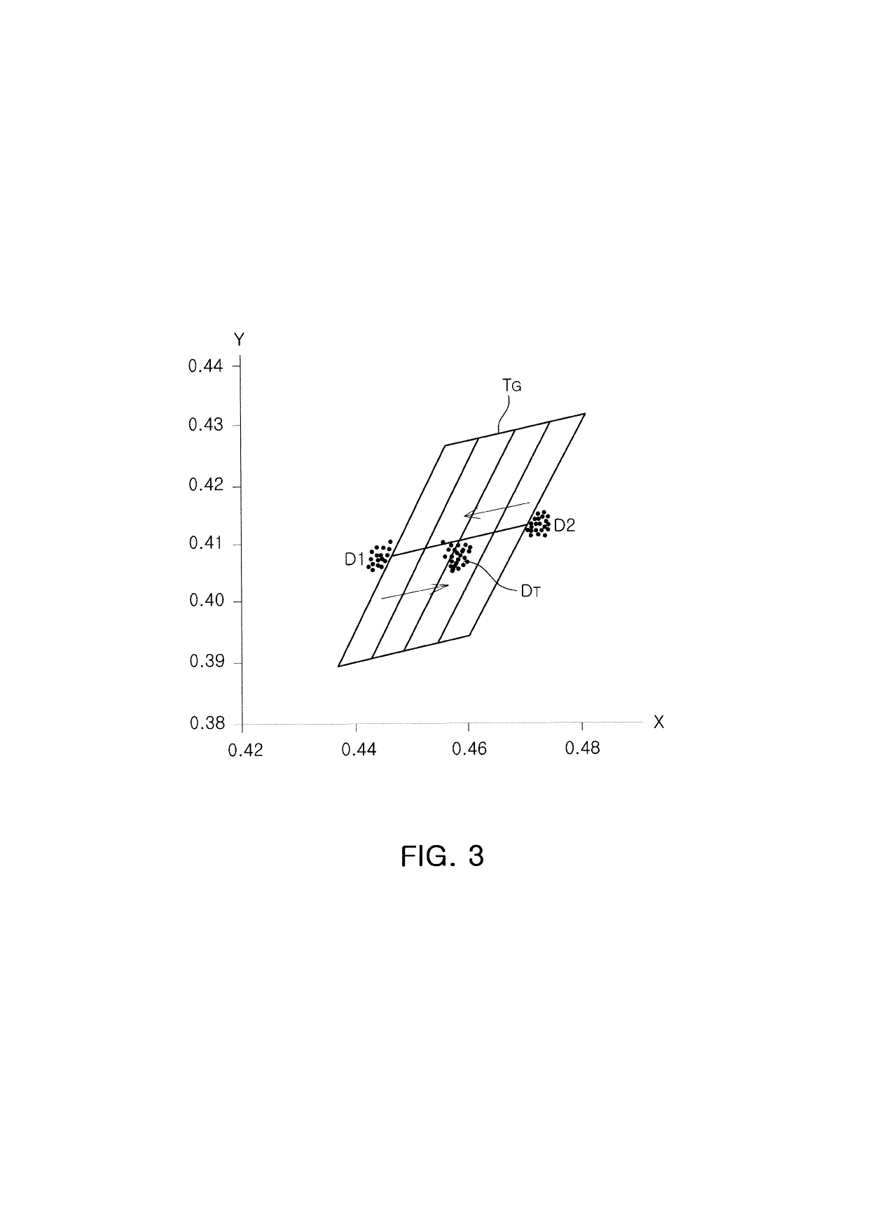

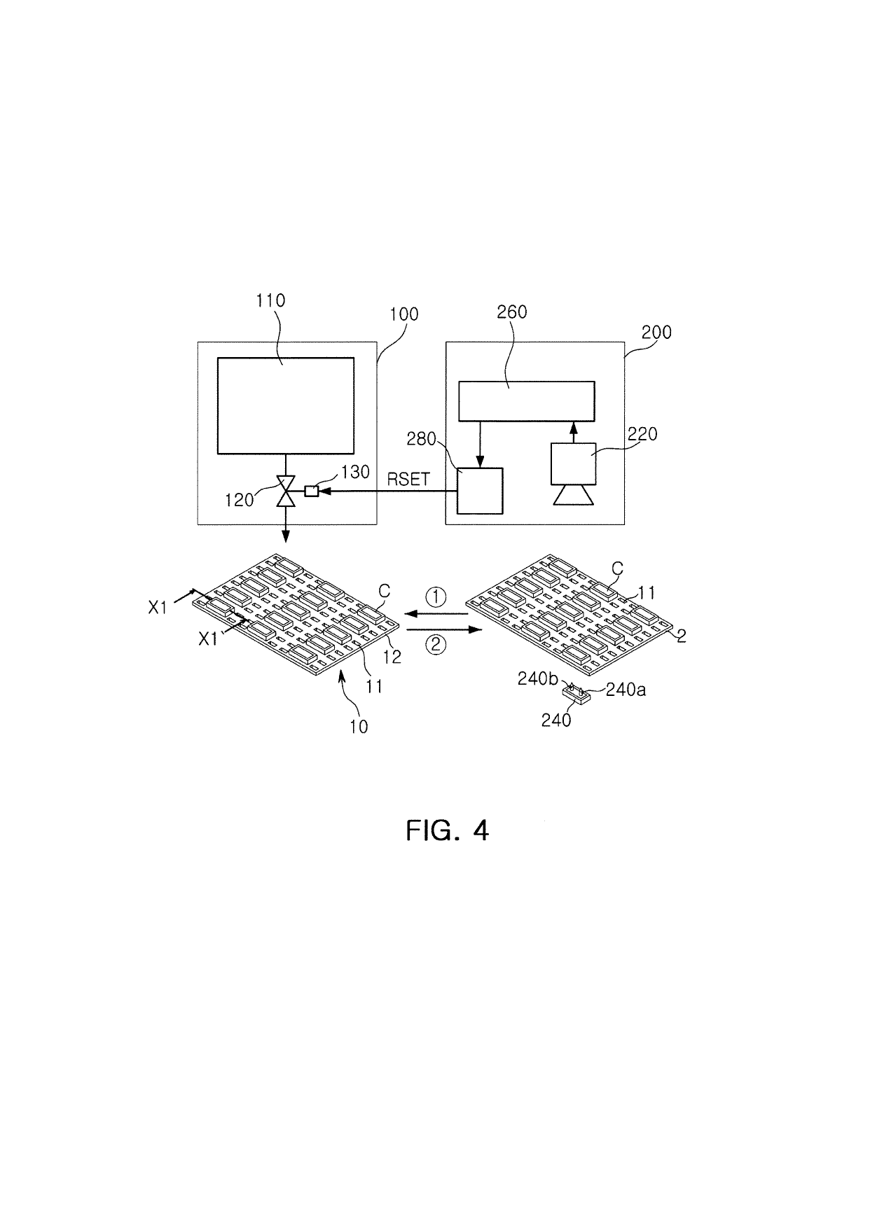

Operation S31 may be performed using a dispensing apparatus. The at least one LED package may be a LED package which was previously processed in a lead frame set, and a portion of a plurality of LED packages to be processed. For example, the at least one package may be any LED packages previously processed in a lead frame set which comprises by a plurality of LED packages. In this example, the lead frame set may be a lead frame plate molded to obtain a plurality of LED packages. The lead frame set may indicate a form in which LED chips are mounted on each package region and may also include a mold for a package body (for example, see reference numeral “10” of FIG. 4).

The LED package according to the embodiment of the present disclosure may include a blue LED chip. The phosphor-containing fluid resin may be yellow phosphor or may be a mixture of red and green phosphors, and may have a mixed form in which at least one of the red and green phosphors is mixed with a yellow phosphor.

In a subsequent operation S33, color coordinates of white light emitted from the at least one LED package may be measured.

In operation S31, prior to operation S33, a predetermined discharge amount of a phosphor-containing fluid resin may be set to have a value satisfying a target color coordinates range. However, this target color coordinates range may not achieved due to an error in the mixing proportion or various process errors which may occur in an actual process. The color coordinates measured in an actual process in which an error is generated may be different from the target color coordinates range.

These operation S31 and S33 may be continuously performed before the phosphor-containing fluid resin dispensed to an LED package is cured. As such, the present technology simplifies the process of achieving the target color coordinates range by implementing the dispensing S31 and measuring S33 steps prior to any curing process. The present target color coordinates range described above reflects an occurrence of errors before and after the phosphor-containing fluid resin is cured, unlike a generally used target color coordinates range provided after the phosphor-containing fluid resin is cured.

As shown in FIG. 2, a distribution that is deviated from the target color coordinates range TG may be provided. For example, in a case in which a discharge amount of the phosphor-containing fluid resin is relatively low, a blue shift may occur as represented as D1. On the other hand, in a case in which the discharge amount of the phosphor-containing fluid resin is relatively high or in excess, a red or yellow shift may occur as represented as D2.

Next, in operation S35, the discharge amount of the phosphor-containing fluid resin may be adjusted based on a deviation between the measured color coordinates and the target color coordinate. In this manner, the target color coordinate can be obtained.

In other words, the discharge amount of the phosphor-containing fluid resin may be reset such that the discharge amount is within a target color coordinates range taking into account the tendency and magnitude of deviation from the measured color coordinates due to deviation. For example, as shown in FIG. 3, in the case of D1 having a blue shift, the discharge amount of the phosphor-containing fluid resin may be reset so as to increase an amount of phosphor and may be adjusted to correspond to the target color coordinates range TG. On the other hand, in D2 having a red or yellow shift, the discharge amount of the phosphor-containing fluid resin may be reset so as to decrease the amount of phosphor and may be adjusted to correspond to the target color coordinates range TG.

In subsequent operation S37, the reset discharge amount of the phosphor-containing fluid resin described above may be transmitted to a preceding dispensing apparatus such that the reset discharge amount may then be applied to another LED package to be subsequently processed.

Since the reset discharge amount of the phosphor-containing fluid resin described above is based on achieving a target color coordinates range with regard to LED packages manufactured under uniform conditions, an LED package satisfying the same target color coordinates conditions DT may be easily obtained.

Finally, a LED package having particular target color coordinates may be manufactured by curing the phosphor-containing fluid resin dispensed to the LED package obtained using the process described above in which the reset discharge amount of the phosphor-containing fluid resin his applied.

As described above, in order to obtain a more precise process, the target color coordinates range may be provided before the phosphor-containing fluid resin is cured. This process reflects the occurrence of errors before and after the phosphor-containing fluid resin is cured. In contrast, conventional processes provide a target color coordinates range after the phosphor-containing fluid resin is cured. Therefore, the present technology achieves more precise target color coordinates.

In the process according to the present embodiment, the at least one LED package is at least one LED package provided in a lead frame set on which the plurality of LED packages are disposed. In this case, another LED package to which a reset discharge amount of the phosphor-containing fluid resin is dispensed is disposed on the same or a different lead frame as the at least one LED package. In a specific case, the another LED package may further include a plurality of other LED packages in another lead frame set. For example, this case may also be applied to another lead frame set disposed in a different lot.

FIG. 4 schematically shows a dispensing apparatus according to another embodiment of the present disclosure. A dispensing apparatus shown in FIG. 4 may include a dispenser 100 dispensing the phosphor-containing fluid resin and a discharge amount adjuster 200 which adjusts a discharge amount of the phosphor-containing fluid resin in order to obtain target color coordinates.

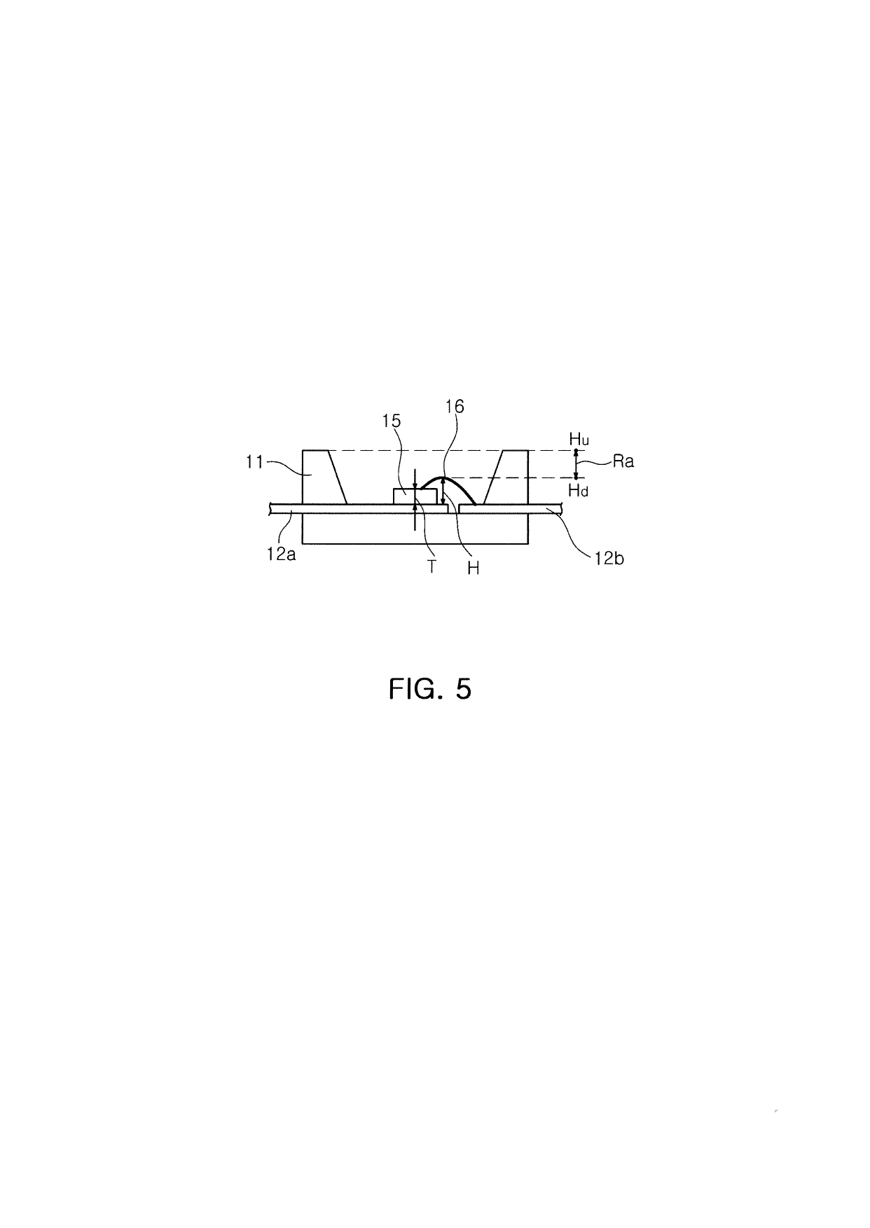

An LED package form 10, applied to the dispensing apparatus according to the present embodiment, is illustrated as an example of a lead frame set 12 on which the plurality of LED packages described above are disposed. The lead frame set 12 may be cut into individual package units and these individual package units may be provided as an LED package shown in FIG. 5. The LED package shown in FIG. 5 may include one pair of lead frames 12a and 12b and a package body 11 providing a cavity C while integrating the lead frames 12a and 12b. An LED chip 15 may be mounted on a lead frame 12a exposed to the cavity C, and the LED chip 15 may be connected to another lead frame 12b by a wire 16.

The dispenser 100 employed in the present embodiment may include a fluid resin storage unit 110, a discharge unit 120 connected to the fluid resin storage unit 110, and a discharge amount control unit 130 controlling a discharge amount of the phosphor-containing fluid resin discharged from the discharge unit 120.

The fluid resin storage unit 110 may store a phosphor-containing fluid resin mixed with a phosphor and a transparent fluid resin according to a pre-set mixing proportion. The discharge unit 120 may be configured to dispense the phosphor-containing fluid resin to the cavity C of the LED package. In addition, the discharge amount control unit 130 may be connected to the discharge unit 120 to control a discharge amount of the phosphor-containing fluid resin discharged from the discharge unit 120.

The discharge amount adjuster 200 used in the present embodiment may transmit a control signal RSET to the discharge amount control unit 130. The RSET signal may represent resetting a discharge amount to satisfy a target color coordinates range and this resetting discharge amount may be based on actually measured color coordinates information of the LED package.

The discharge amount adjuster 200 may include an electric driving unit 240 which electrically drives an LED package, and a color coordinates measuring unit 220 which detects color coordinates of light emitted from the LED package. The electric driving unit 240 may be disposed in a lower part of the lead frame set 10 and may include probe parts 240a and 240b which are connected to the lead frame of an individual LED package.

Further, the discharge amount adjuster 200 may include a discharge amount calculation unit 260 configured to calculate a discharge amount of the phosphor-containing fluid resin, based on a deviation between the measured color coordinates and target color coordinates. In this manner, the target color coordinates can be obtained. In addition, discharge amount adjuster 200 may include a control signal transmission unit 280 which transmits to the discharge control unit 130, a control signal RSET based on the calculated discharge amount.

As shown in FIG. 4, the discharge amount adjuster 200 including the color coordinates measuring unit 220 may be integrally disposed with the dispenser 100 so as to measure color coordinates provided before the phosphor-containing fluid resin dispensed to the LED package is cured.

A minimum discharge amount of the phosphor-containing fluid resin in the case of the LED package shown in FIG. 5 may be set to be larger than an amount based on the thickness T of the LED chip 15. However, in an embodiment including wire 16, a minimum discharge amount may be generally set such that the height of the wavelength conversion unit is higher than the height H of the wire in order to protect the wire 16. The height of the wavelength conversion unit described here may be defined as a minimum height Hd. On the other hand, since a maximum discharge amount of the phosphor-containing fluid resin is limited by the depth Hu of the cavity, the maximum discharge amount may be determined by the depth of the cavity C.

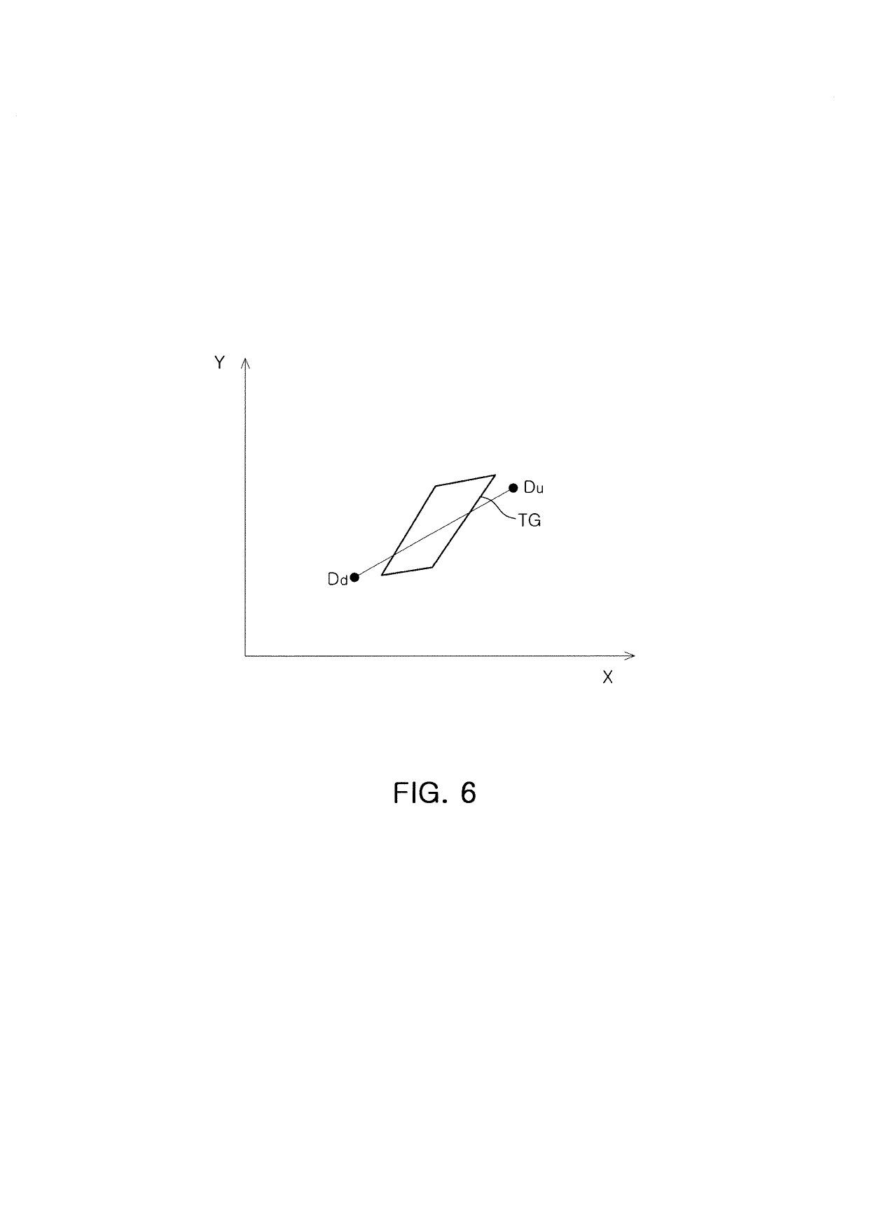

The discharge amount of the phosphor-containing fluid resin may also be limited to a maximum amount Du and a minimum amount Dd based on the maximum height Hu and the minimum height Hd of a resin packing part as described above. In addition, a change in color coordinates according to an allowable adjustment range may be limited by the a maximum amount and a minimum amount as shown in FIG. 6. Therefore, in order to adjust color coordinates (or a deviation in color temperatures) exceeding an actual allowable adjustment amount, the discharge amount should accompany the adjustment in the mixing proportion of phosphor and a transparent fluid resin through a separate process. An example of such a transparent fluid resin is a silicon resin.

In resetting the discharge amount of the phosphor-containing fluid resin, the discharge amount of the phosphor-containing fluid resin may be calculated using a correlation between the deviation and the discharge amount so as to compensate for the deviation.

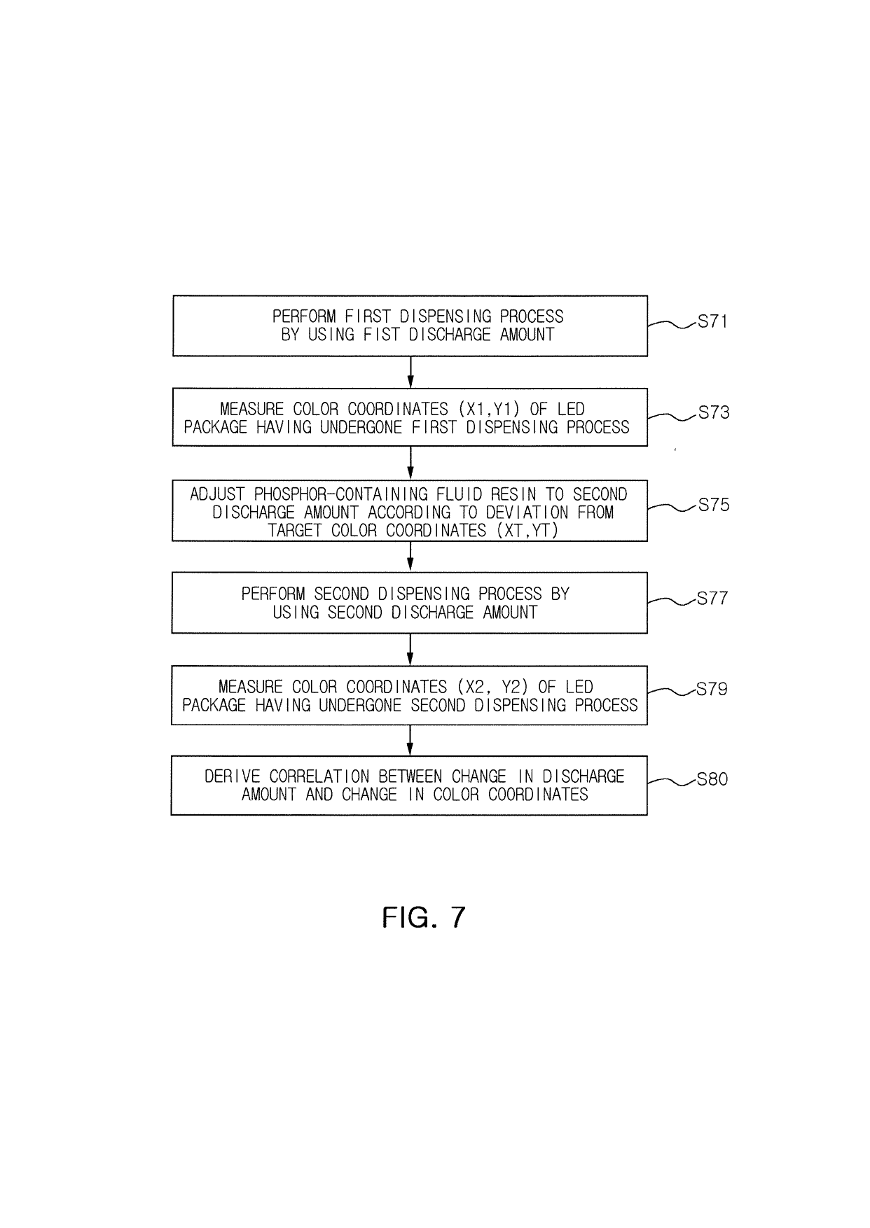

As shown in FIG. 7, the correlation between the deviation and the discharge amount may be obtained by dispensing different discharge amounts of the phosphor-containing fluid resin to two LED packages, measuring color coordinates of white light emitted from the two LED packages, and then performing a calculation by using a change in the discharge amount and the deviation of the color coordinates of the two LED packages.

As shown in FIG. 7, in operation S71, a first dispensing process may be performed with regard to an LED package by using a first discharge amount of the phosphor-containing fluid resin. The LED package to which the first dispensing process is applied may be a portion of all LED packages to be processed.

In operation S73, color coordinates (X1,Y1) of the LED package having undergone the first dispensing process described above may be measured. This process may also be performed continuously following the dispensing process, in a state before the fluid resin is cured.

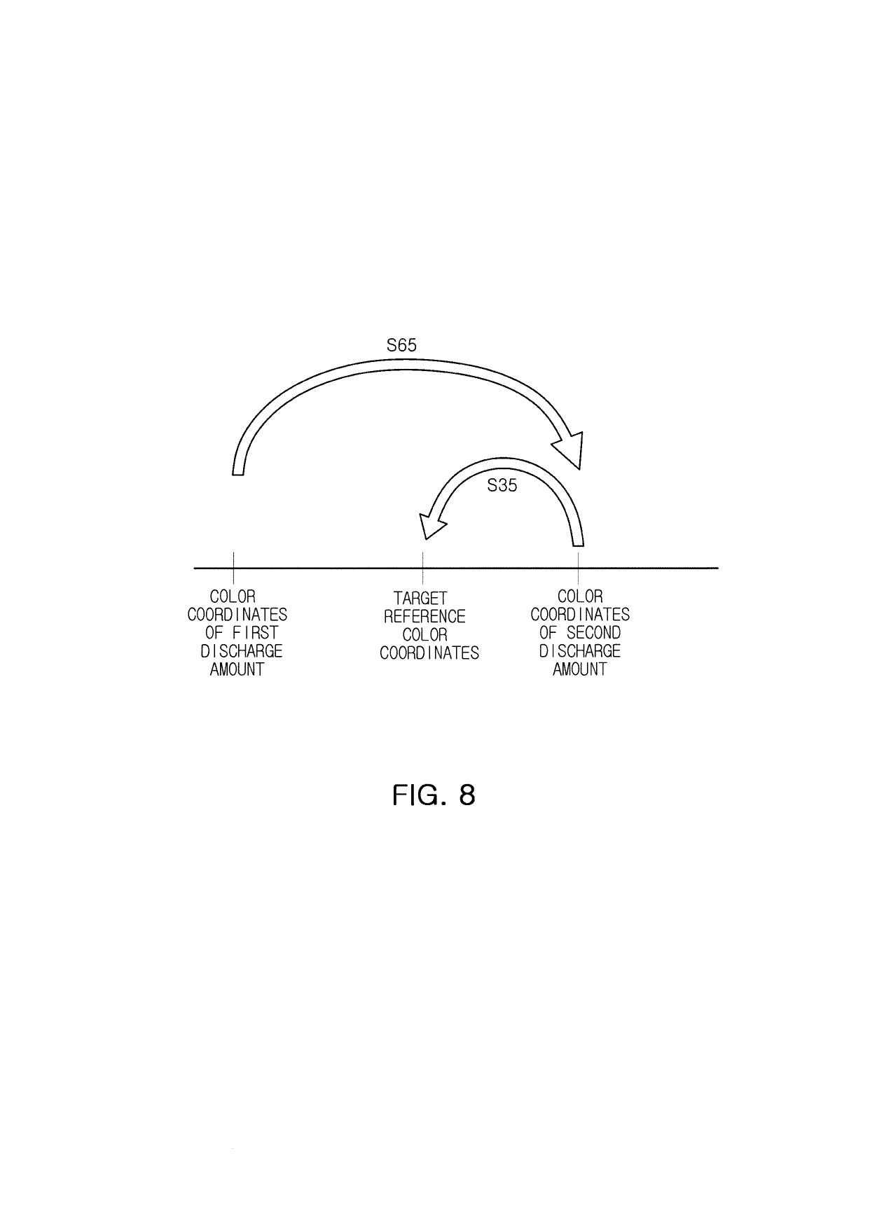

Next, in the same manner as that of operation S75, the phosphor-containing fluid resin may be adjusted to a second discharge amount based on a deviation from the target color coordinates (Xt,Yt). Although a discharge amount of the phosphor-containing fluid resin is set as the first or second discharge amount, a change in color coordinates based on a change in the discharge amount may be obtained. In order to achieve a more precise measurement, the second discharge amount is sufficiently different from the color coordinates of the first discharge amount so as to allow the setting of a target range of reference color coordinates that is between the color coordinates of the first and second discharge amounts as shown in FIG. 8. Here, the target reference color coordinates refer to color coordinates corresponding to the center of the target color coordinates.

Subsequently, in a similar manner to that of respective operations S71 and S73, a second dispensing process may be performed with regard to another LED package by using the second discharge amount of the phosphor-containing fluid resin in operation S77, and color coordinates (X2,Y2) of the LED package to which the second discharge amount is dispensed and then measured in operation S79.

As such, a change in color coordinates based on a change in a discharge amount of the phosphor-containing fluid resin may be calculated in operation S80 by two color coordinates based on the first and second discharge amounts obtained as described above. When the color coordinates based on a predetermined discharge amount, which is calculated on the basis of a correlation between the deviation and the discharge amount in operation S35 of FIG. 1, does not satisfy a target color coordinates range, an adjusted amount with regard to the discharge amount may be set so as to satisfy a required color coordinates range.

As set forth above, according to an embodiment of the present disclosure, a drop in production yield may be significantly reduced and target color properties may be achieved through a simplified process by allowing information regarding an appropriate discharge amount to be feedbacked after measuring color coordinates with respect to a portion of an LED package.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

What is claimed is:

1. A method of manufacturing a light emitting diode (LED) package, comprising:
dispensing a predetermined discharge amount of a phosphor-containing fluid resin to at least one LED package;
measuring color coordinates of white light emitted from the at least one LED package;
adjusting the discharge amount of the phosphor-containing fluid resin, based on a deviation between the measured color coordinates and target color coordinates; and
dispensing the adjusted discharge amount of the phosphor-containing fluid resin to another LED package.

2. The method of claim 1, further comprising curing the phosphor-containing fluid resin dispensed to the another LED package

3. The method of claim 1, wherein the measuring of the color coordinates is performed before the dispensed phosphor-containing fluid resin is cured.

4. The method of claim 1, wherein the LED package includes a blue LED chip, and the phosphor-containing fluid resin includes at least one of a yellow phosphor and a mixture of red and green phosphors.

5. The method of claim 4, wherein the adjusting of the discharge amount of the phosphor-containing fluid resin is performed to increase the predetermined discharge amount when the deviation corresponds to a blue shift and to reduce the predetermined discharge amount when the deviation corresponds to a red shift or yellow shift.

6. The method of claim 1, wherein the adjusting of the discharge amount of the phosphor-containing fluid resin is performed within an adjustable range to be allowed in the LED package.

7. The method of claim 1, wherein the adjusting of the discharge amount of the phosphor-containing fluid resin is performed to calculate the discharge amount of the phosphor-containing fluid resin by using a correlation between the deviation and the discharge amount to compensate for the deviation.

8. The method of claim 7, wherein the correlation between the deviation and the discharge amount is obtained by dispensing different discharge amounts of the phosphor-containing fluid resin to two LED packages, measuring the color coordinates of the white light emitted from the two LED packages, and then performing a calculation by using a change in the discharge amount and the deviation of the color coordinates of the two LED packages.

9. The method of claim 1, wherein the at least one LED package is at least one LED package provided in a lead frame on which a plurality of the LED packages are disposed, and the another LED package is another LED package balanced in the lead frame set on which the plurality of the LED packages are disposed.

10. The method of claim 9, wherein the another LED package further includes other LED packages in another lead frame set.

11. A dispensing apparatus comprising:
a dispenser including a fluid resin storage unit storing a phosphor-containing fluid resin, a discharge unit dispensing the phosphor-containing fluid resin to an LED package, and a discharge amount control unit controlling a discharge amount of the phosphor-containing fluid resin discharged from the discharge unit; and
a discharge amount adjuster including an electric driving unit electrically driving the LED package, a color coordinates measuring unit detecting color coordinates of light emitted from the LED package, a discharge amount calculation unit calculating the discharge amount of the phosphor-containing fluid resin, based on a deviation between the measured color coordinates and target color coordinates, to obtain the target color coordinates, and a control signal transmission unit transmitting a control signal based on the calculated discharge amount to the discharge amount control unit.

12. The dispensing apparatus of claim 11, wherein the color coordinates measuring unit is integrally disposed with the dispenser so as to measure color coordinates provided before the phosphor-containing fluid resin dispensed to the LED package is cured.

13. A method of manufacturing a light emitting diode (LED) package comprising:
(a) dispensing a discharge amount of a phosphor-containing fluid resin to at least one LED package;
(b) measuring color coordinates of white light emitted from the at least one LED package;
(c) adjusting the discharge amount of the phosphor-containing fluid resin such that the measured color coordinates become approximate to the target color coordinates; and
(d) dispensing the adjusted discharge amount of the phosphor-containing fluid resin to another LED package.

14. The method of claim 13, further comprising curing the phosphor-containing fluid resin dispensed to the another LED package.

15. The method of claim 13 further comprising repeating the steps (a)-(d) on different LED packages.

16. The method of claim 13, wherein the measuring of the color coordinates is performed before the dispensed phosphor-containing fluid resin is cured.

17. The method of claim 13, wherein the LED package includes a blue LED chip, and the phosphor-containing fluid resin includes at least one of a yellow phosphor and a mixture of red and green phosphors.

18. The method of claim 17, wherein the adjusting of the discharge amount of the phosphor-containing fluid resin is performed to increase the discharge amount when a deviation between the measured color coordinates and the target color coordinates range corresponds to a blue shift and to reduce the discharge amount when the deviation corresponds to a red shift or yellow shift.

19. The method of claim 13, wherein the adjusting of the discharge amount of the phosphor-containing fluid resin is performed to calculate the discharge amount of the phosphor-containing fluid resin by using a correlation between a deviation between the measured color coordinates and the target color coordinates range and the discharge amount to compensate for the deviation.

20. The method of claim 19, wherein the correlation between the deviation and the discharge amount is obtained by preparing two LED packages having different discharge amounts of the phosphor-containing fluid resin dispensed thereto, measuring the color coordinates of the white light emitted from the two LED packages, and then performing a calculation by using a change in the discharge amount and the deviation of the color coordinates of the two LED packages.
